(19) United States
(12) Patent Application Publication
(10) Pub. No.: US 2014/0212534 A1
(43) Pub. Date: Jul. 31, 2014

(54) Fabrication of High-Throughput Nano-Imprint Lithography Templates

(71) Applicants: Edward B. Fletcher, Austin, TX (US); Frank Y. Xu, Round Rock, TX (US); Weijun Liu, Cedar Park, TX (US); Fen Wan, Austin, TX (US); Marlon Menezes, Austin, TX (US); Kosta S. Selinidis, Austin, TX (US)

(72) Inventors: Edward B. Fletcher, Austin, TX (US); Frank Y. Xu, Round Rock, TX (US); Weijun Liu, Cedar Park, TX (US); Fen Wan, Austin, TX (US); Marlon Menezes, Austin, TX (US); Kosta S. Selinidis, Austin, TX (US)

(73) Assignee: MOLECULAR IMPRINTS, INC., Austin, TX (US)

(21) Appl. No.: 13/754,015

(22) Filed: Jan. 30, 2013

(51) Int. Cl. B29C 59/02; C23C 16/40

(52) U.S. Cl. CPC B29C 59/02; C23C 16/401
USPC 425/385; 427/248.1; 216/11; 427/579

(57) ABSTRACT

An imprint lithography template includes a porous material defining a multiplicity of pores with an average pore size of at least about 0.4 nm. The porous material includes silicon and oxygen, and a ratio of Young's modulus (E) to relative density of the porous material with respect to fused silica (ρₚₒᵣₒᵤₛ/ρ_{fused silica}) is at least about 10:1. A refractive index of the porous material is between about 1.4 and 1.5. The porous material may form an intermediate layer or a cap layer of an imprint lithography template. The template may include a pore seal layer between a porous layer and a cap layer, or a pore seal layer on top of a cap layer.

### CROSS-REFERENCE TO RELATED APPLICATIONS

This application is a continuation of U.S. application Ser. No. 12/604,094 filed Oct. 22, 2009, which claims the benefit under 35 U.S.C. §119(e)(1) of U.S. Provisional Application Ser. Nos. 61/107,720, filed Oct. 23, 2008; 61/110,051, filed Oct. 31, 2008; and 61/227,395, filed Jul. 21, 2009, all of which are hereby incorporated by reference herein.

### TECHNICAL FIELD

The present invention relates to high-throughput nano-imprint lithography templates, and fabrication thereof.

### BACKGROUND

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate; therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

### SUMMARY

In one aspect, an imprint lithography template includes a porous material defining a multiplicity of pores with an average pore size of at least about 0.4 nm. The porous material includes silicon and oxygen. A refractive index of the porous material is between about 1.4 and about 1.5, and a ratio of Young's modulus (E) to relative density of the porous material with respect to fused silica (ρₚₒᵣₒᵤₛ/ρ_{fused silica}) is at least about 10:1.

Implementations may include one or more of the following features. For example, the Young's modulus of the porous material may be at least about 2 GPa, at least about 5 GPa, at least about 10 GPa, or at least about 20 GPa. The relative density of the porous material with respect to fused silica may be at least about 50% or at least about 65%. The porous material may include SiOₓ, and 1≦x≦2.5. The pores may be substantially closed or interconnected. Interconnected pores may form channels in the porous material.

In some cases, the template further includes a base layer and a cap layer, and the porous material forms a layer between the base layer and the cap layer. The cap layer may be porous. The cap layer may be etched or patterned such that protrusions extend from a surface of the cap layer. The base layer may include fused silica. Stress in the porous material may be neutral to compressive. The porosity of the porous material, or porous layer, may be non-uniform or asymmetric. The porous material may have a non-uniform porosity gradient. A non-uniform porous layer may be achieved by changing one or more parameters during the formation of a porous layer. The parameter to be changed may be a vapor deposition process parameter. A vapor deposition process may include atomic layer deposition. In some cases, an imprint lithography template may include one or more layers (e.g., an adhesion layer) between the base layer and the porous layer.

The porosity of a porous layer (e.g., between a base layer and a cap layer) may range from about 0.1% to about 60% (e.g., about 1% to about 20%, or about 5% to about 15%). In some cases, the porosity of a porous layer may be at least about 10%, or at least about 20%. The porosity of a cap layer may range from about 0.1% to about 20% (e.g., from about 1% to about 20%, or from about 3% to about 15%).

The template may further include a seal layer adhered to the cap layer. The seal layer may be is permeable to helium gas in contact with the seal layer and substantially impermeable to species larger than helium. The seal layer may include silicon oxide. The seal layer may be positioned between the porous layer and the cap layer. The seal layer may be conformal and/or uniform in thickness. A thickness of the seal layer may be less than about 10 nm, less than about 5 nm, less than about 3 nm, or about twice the pore radius. In some cases, the seal layer may be selected to interact with a mold release agent.

In another aspect, forming an imprint lithography template includes forming a layer of porous material on a surface of an imprint lithography template. The porous layer defines a multiplicity of pores with an average pore size of at least about 0.4 nm. The porous material includes oxygen and silicon. A refractive index of the porous material is between about 1.4 and about 1.5, and a ratio of Young's modulus (E) to relative density of the porous material with respect to fused silica (ρₚₒᵣₒᵤₛ/ρ_{fused silica}) is at least about 10:1.

In some implementations, a second layer may be formed on the porous layer. In some cases, the porous layer may be etched to form a patterned layer. Forming the porous layer may include etching the porous layer. Forming the porous layer may include a vapor deposition process, such as plasma enhanced chemical vapor deposition. The porosity of the porous layer may be substantially uniform or non-uniform. For example, the porosity may be asymmetric, or the porosity gradient may be non-uniform, such that a portion of the layer to be etched is less porous than other portions of the layer.

An etch stop layer may be formed between the surface of the imprint lithography template and the porous layer. A seal layer may be formed on the surface of the porous layer. A cap layer may be formed on a surface of the seal layer. Alternatively, a cap layer may be formed on the porous layer, and a seal layer may be formed on the cap layer. In some cases, the porous layer is etched to form a patterned layer. A marker region may be formed between the surface of the imprint lithography template and the porous layer. The marker region may serve as a thin film optical metrology marker on the base layer. In some cases, a region of a base layer may be masked while forming the porous layer to create a recess in the porous layer for film thickness metrology. In some cases, a porous layer (e.g., an intermediate porous layer or a porous cap layer) may be polished, for example, using a chemical-mechanical planarization process. In some cases, a mesa may be etched in a porous layer or a base layer.

In another aspect, forming a layer on an imprint lithography template includes positioning an imprint lithography template defining a multiplicity of pores in a vacuum chamber, evacuating the chamber a first time, purging the chamber with a first inert gas, and evacuating the chamber a second time. The chamber may then be saturated with a second inert gas. A silicon-containing gas and one or more other gases may be introduced into the chamber, and a plasma process may be initiated to deposit a silicon-containing layer on the surface of the imprint lithography template. This process substantially fills pores in the porous layer of the imprint lithography template with an inert gas before the silicon-containing layer is deposited on the porous layer. With the pores in the porous layer filled with inert gas, reactants used to form the silicon-containing layer are inhibited from diffusing into the porous layer and clogging the pores, changing the chemical and physical nature of the porous layer. Thus, the porous layer remains substantially uniform, and does not become more dense near the silicon-containing layer.

In one aspect, an imprint lithography template includes a first layer and a second layer. The second layer is a patterned layer of an imprint lithography template. Two or more intermediate layers are positioned between the first layer and the second layer. At least one of the intermediate layers is a porous layer and at least one of the intermediate layers is a stress relief layer configured to reduce a force acting on the porous intermediate layer. In another aspect, an imprint lithography template includes a first layer, a second layer, and an intermediate layer positioned between the first layer and the second layer. The second layer is a patterned layer of an imprint lithography template, and the intermediate layer is configured to reduce a force acting on the patterned second layer. In another aspect, an imprint lithography template includes a first layer and one or more layers on the first layer. At least one of the one or more layers is porous. A stress relief layer may be positioned on the back side of the template to counter a force produced by the layer or layers on the first layer.

In some implementations, the first layer is a base layer and the second layer is a top layer. The top layer may be a cap layer. The stress relief layer provides a compressive force, and the compressive force reduces a tensile force acting on the porous intermediate layer. In other implementations, the stress relief layer provides a tensile force, and the tensile force reduces a compressive force acting on the porous intermediate layer. In some cases, a neutral to compressive stress state is maintained in the porous intermediate layer during static and dynamic conditions, such as template bending during separation.

The porous intermediate layer may be positioned between two stress relief layers, the stress relief layer may be positioned between two porous intermediate layers, or any combination thereof. The stress relief layer may include a metal, metal oxide, metal nitride, or metal carbide. In some cases, the stress relief layer is porous (i.e., more porous or less dense than fused silica).

In one aspect, an imprint lithography template includes a first layer, a second layer, and an intermediate layer positioned between the first layer and the second layer of the imprint lithography template. The intermediate layer is configured to allow assessment of a thickness of the second layer based on a difference in physical properties between the intermediate layer and the second layer.

In some implementations, the first layer is a base layer and the second layer is a top layer or a cap layer. The intermediate layer may an etch stop layer. The intermediate layer may include a metal, metal oxide, metal carbide, or metal nitride. The intermediate layer may provide stress relief for the top layer. The physical property may be an optical property, such as transmittance or reflectance. In some cases, the intermediate layer is non-continuous. That is, the intermediate layer may include one or more separate regions (e.g., marker regions). A thickness of the intermediate layer may be less than about 30 nm, less than about 20 nm, less than about 10 nm, less than about 5 nm, or less than about 3 nm. Thus, the intermediate layer, even if discontinuous, may not introduce a noticeable perturbation to the second layer. In some cases, the second layer may be polished to form a substantially smooth surface. When marker regions are used, the regions may be located outside of the area occupied by the mesa or patterned portion of an imprint lithography template.

Aspects and implementations described herein may be combined in ways other than described above. Other aspects, features, and advantages will be apparent from the following detailed description, the drawings, and the claims.

### BRIEF DESCRIPTION OF DRAWINGS

FIG. 1 illustrates a simplified side view of a lithographic system.

FIG. 2 illustrates a simplified side view of the substrate shown in FIG. 1 having a patterned layer positioned thereon.

FIG. 3 illustrates a side view of a gas pocket trapped between a substrate and a template.

FIG. 4 illustrates a side view of a template with a porous layer.

FIG. 5 illustrates a template with an asymmetric porous layer.

FIG. 6 illustrates a unitary porous template.

FIG. 7 illustrates a porous template with no base layer.

FIG. 8A illustrates a porous template with a sealed cap layer.

FIG. 8B illustrates a porous template with a sealed porous layer.

FIG. 9 is a flow chart for a process to form a cap layer on a porous layer with reduced clogging of pores in the porous layer.

FIG. 10 illustrates forming a cap layer on a porous layer with reduced clogging of the porous layer.

FIG. 11 illustrates a side view of a template with tensile stress associated with a porous layer.

FIG. 12 illustrates a side view of a template with a porous layer and a relief layer.

FIGS. 13A and 13B illustrate side views of a template with a porous layer and multiple relief layers.

FIG. 14 illustrates a side view of a template with multiple porous layers and multiple relief layers.

FIGS. 15A and 15B illustrate reduction of stress on a nano-imprint lithography template with the addition of a stress relief layer opposite the mold.

FIG. 16 illustrates a nano-imprint lithography template with an etch stop layer.

FIGS. 17A and 17B illustrate a nano-imprint lithography template with a marker region for use as a metrology marker.

FIGS. 18A and 18B are photographs that show spreading of imprint resist between a substrate and a template with a porous intermediate layer.

FIGS. 19A, 19B, and 19C are photographs that show spreading of imprint resist between a substrate and a template without a porous layer.

FIGS. 20A and 20B are photographs that show rapid wicking of imprint resist into a porous template.

FIGS. 21A and 21B are photographs that show slow wicking of imprint resist into a template with a porous layer and a cap layer.

FIGS. 22A through 22D are photographs that show filling of voids between droplets in contact with a template as the droplets spread.

### DETAILED DESCRIPTION

An exemplary nano-fabrication technique in use today is commonly referred to as imprint lithography. Exemplary imprint lithography processes are described in detail in numerous publications, such as U.S. Patent Application Publication No. 2004/0065976, U.S. Patent Application Publication No. 2004/0065252, and U.S. Pat. No. 6,936,194, all of which are hereby incorporated by reference herein.

An imprint lithography technique disclosed in each of the aforementioned U.S. patent application publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and the formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

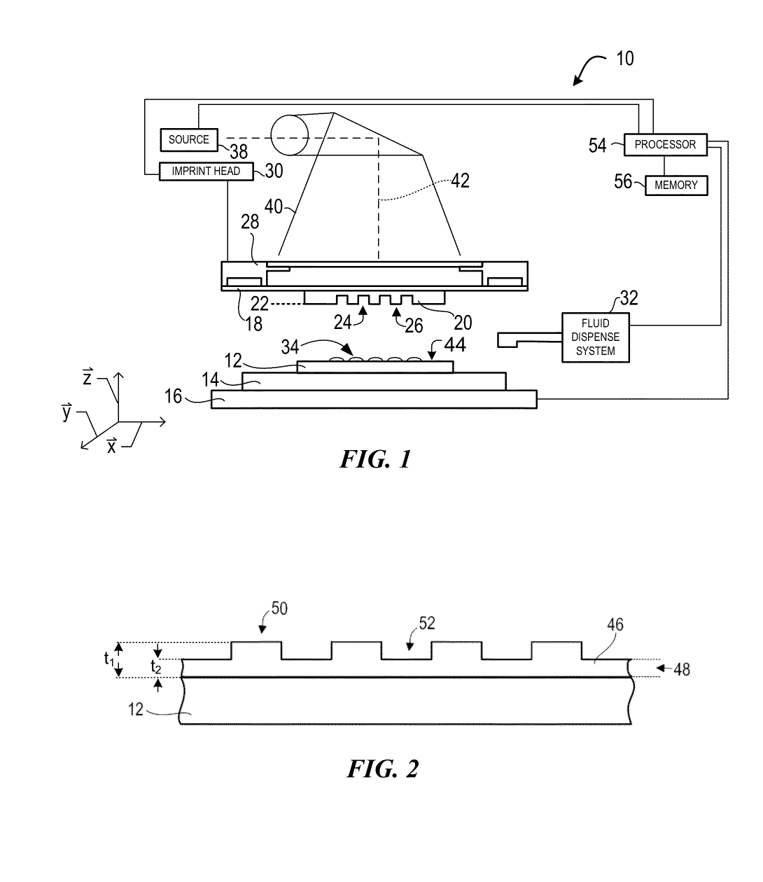

Referring to FIG. 1, illustrated therein is a lithographic system 10 used to form a relief pattern on substrate 12. An imprint lithography stack may include substrate 12 and one or more layers (e.g., an adhesion layer) adhered to the substrate. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electromagnetic, and the like, or any combination thereof. Exemplary chucks are described in U.S. Pat. No. 6,873,087, which is hereby incorporated by reference herein.

Substrate 12 and substrate chuck 14 may be further supported by stage 16. Stage 16 may provide motion about the x-, y-, and z-axes. Stage 16, substrate 12, and substrate chuck 14 may also be positioned on a base (not shown).

Spaced-apart from substrate 12 is a template 18. Template 18 may include a mesa 20 extending therefrom towards substrate 12, mesa 20 having a patterning surface 22 thereon. Further, mesa 20 may be referred to as mold 20. Template 18 and/or mold 20 may be formed from such materials including, but not limited to, fused-silica, quartz, silicon, organic polymers, siloxane polymers, borosilicate glass, fluorocarbon polymers, metal, hardened sapphire, and the like, or any combination thereof. As illustrated, patterning surface 22 comprises features defined by a plurality of spaced-apart recesses 24 and/or protrusions 26, though embodiments of the present invention are not limited to such configurations. Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electromagnetic, and/or other similar chuck types. Exemplary chucks are further described in U.S. Pat. No. 6,873,087, which is hereby incorporated by reference herein. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit polymerizable material 34 on substrate 12. Polymerizable material 34 may be positioned upon substrate 12 using techniques such as drop dispense, spin-coating, dip coating, chemical vapor deposition (CVD), physical vapor deposition (PVD), thin film deposition, thick film deposition, and the like, or any combination thereof. Polymerizable material 34 (e.g., imprint resist) may be disposed upon substrate 12 before and/or after a desired volume is defined between mold 20 and substrate 12 depending on design considerations. Polymerizable material 34 may include components as described in U.S. Pat. No. 7,157,036 and U.S. Patent Application Publication No. 2005/0187339, both of which are hereby incorporated by reference herein.

Referring to FIGS. 1 and 2, system 10 may further comprise an energy source 38 coupled to direct energy 40 along path 42. Imprint head 30 and stage 16 may be configured to position template 18 and substrate 12 in superimposition with path 42. System 10 may be regulated by a processor 54 in communication with stage 16, imprint head 30, fluid dispense system 32, source 38, or any combination thereof, and may operate on a computer readable program stored in memory 56.

Either imprint head 30, stage 16, or both may alter a distance between mold 20 and substrate 12 to define a desired volume therebetween that is substantially filled by polymerizable material 34. For example, imprint head 30 may apply a force to template 18 such that mold 20 contacts polymerizable material 34. After the desired volume is substantially filled with polymerizable material 34, source 38 produces energy 40, e.g., broadband ultraviolet radiation, causing polymerizable material 34 to solidify and/or cross-link conforming to shape of a surface 44 of substrate 12 and patterning surface 22, defining a patterned layer 46 on substrate 12. Patterned layer 46 may include a residual layer 48 and a plurality of features shown as protrusions 50 and recessions 52, with protrusions 50 having a thickness t₁ and residual layer 48 having a thickness t₂.

The above-described system and process may be further implemented in imprint lithography processes and systems referred to in U.S. Pat. No. 6,932,934, U.S. Patent Application Publication No. 2004/0124566, U.S. Patent Application Publication No. 2004/0188381, and U.S. Patent Application Publication No. 2004/0211754, all of which are hereby incorporated by reference herein.

In nano-imprint processes in which polymerizable material is applied to a substrate by drop dispense or spin coating methods, gases may be trapped inside recesses in the template after the template contacts the polymerizable material. In nano-imprint processes in which polymerizable material is applied to a substrate by drop dispense methods, gases may also be trapped between drops of polymerizable material or imprint resist dispensed on a substrate (e.g., on an imprinting stack). That is, gases may be trapped in interstitial regions between drops as the drops spread.

Gas escape and dissolution rates may limit the rate at which the polymerizable material is able to form a continuous layer on the substrate or the rate at which the polymerizable material is able to fill template features after the template contacts the polymerizable material, thereby limiting throughput in nano-imprint processes. For example, a substrate or a template may be substantially impermeable to a gas trapped between the substrate and the template. In some cases, a polymeric layer adhered to the substrate or the template may become saturated with gas, such that gas between the imprinting stack and the template is substantially unable to enter the saturated polymeric layer, and remains trapped between the template and the substrate. Gas that remains trapped between the template and the substrate may cause filling defects in the patterned layer.

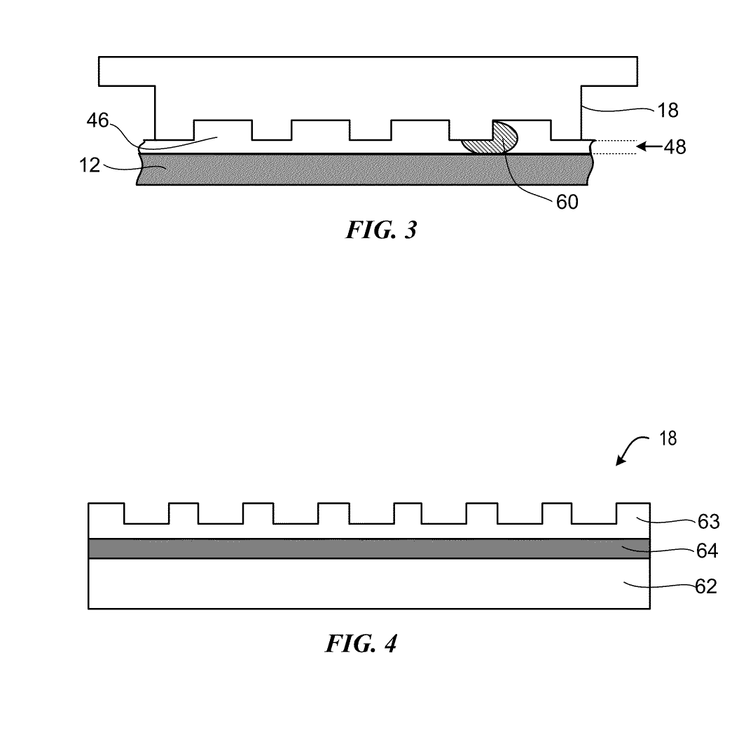

FIG. 3 illustrates gas (or gas pocket) 60 in patterned layer 46 between substrate 12 and template 18. The gas 60 may include, but is not limited to, air, nitrogen, carbon dioxide, helium, or the like. Gas 60 between substrate 12 and template 18 may result in pattern distortion of features formed in patterned layer 46, low fidelity of features formed in patterned layer 46, non-uniform thickness of residual layer 48 across patterned layer 46, or the like.

In an imprint lithography process, gas trapped between the substrate and the template may escape through the polymerizable material, the substrate, or the template. The amount of gas that escapes through any medium may be influenced by the contact area between the trapped gas and the medium. The contact area between the trapped gas and the polymerizable material may be less than the contact area between the trapped gas and the substrate or the template. For example, a thickness of the polymerizable material on a substrate may be less than about 1 μm, or less than about 100 nm. In some cases, a polymerizable material may absorb enough gas to become saturated with the gas before imprinting, such that trapped gas is substantially unable to enter the polymerizable material. In contrast, the contact area between the trapped gas and the substrate or the template may be relatively large.

The gas permeability of a medium may be expressed as P=D×S, in which P is the permeability, D is the diffusion coefficient, and S is the solubility. In a gas transport process, a gas adsorbs onto a surface of the medium, and a concentration gradient is established within the medium. The concentration gradient may serve as the driving force for diffusion of gas through the medium. Gas solubility and the diffusion coefficient may vary based on, for example, packing density of the medium. Adjusting a packing density of the medium may alter the diffusion coefficient and hence the permeability of the medium.

For a multi-layer film, effective permeability may be calculated from a resistance model, such as an analog of an electric circuit described by F. Peng, et al. in J. Membrane Sci. 222 (2003) 225-234 and A. Ranjit Prakash et al. in Sensors and Actuators B 113 (2006) 398-409, which are both hereby incorporated by reference herein. The resistance of a material to the permeation of a vapor is defined as the permeance resistance, Rₚ. For a two-layer composite film with layer thicknesses l₁ and l₂, and corresponding permeabilities P₁ and P₂, permeance resistance may be defined as:

$${R}_{p} = \frac{Δ p}{J} = \frac{1}{( P / l ) A} \qquad ( 1 )$$

in which Δp is the pressure difference across the film, J is the flux, and A is the area. The resistance model predicts

Rₚ=R₁+R₂ (2)

When the cross-sectional area is the same for both materials 1 and 2, equation (2) may be rewritten as:

$$\frac{{l}_{1} + {l}_{2}}{P} = \frac{{l}_{1}}{{P}_{1}} + \frac{{l}_{2}}{{P}_{2}} \qquad ( 3 )$$

A gas may be thought of as having an associated kinetic diameter. The kinetic diameter provides an idea of the size of the gas atoms or molecules for gas transport properties. D. W. Breck, Zeolite Molecular Sieves—Structure, Chemistry, and Use, John Wiley & Sons, New York, 1974, p. 636, which is incorporated by reference herein, lists the kinetic diameter for helium (0.256 nm), argon (0.341 nm), oxygen (0.346 nm), nitrogen (0.364 nm), and other common gases.

In some imprint lithography processes, a helium purge is used to substantially replace air between the template and the substrate or imprinting stack with helium gas. To simplify the comparison between a helium environment and an air environment in an imprint lithography process, the polar interaction between oxygen in air and silica may be disregarded by modeling air as pure argon. Both helium and argon are inert gases, and argon has a kinetic diameter similar to that of oxygen. Unlike oxygen, however, helium and argon do not interact chemically with fused silica or quartz (e.g., in a template or substrate).

Internal cavities (solubility sites) and structural channels connecting the solubility sites allow a gas to permeate through a medium. The gas may be retained in the solubility sites. The size of the internal cavities and the channel diameter relative to the size (or kinetic diameter) of the gas influence the rate at which the gas permeates the medium.

The sizes of individual interstitial solubility sites of fused silica have been shown to follow a log-normal distribution by J. F. Shackelford, “Gas solubility in glasses—principles and structural implications,” J. Non-Cryst. Solids 253 (1999): 231-241, which is incorporated by reference herein. As indicated by the interstitial diameter distribution (mode=0.181 nm; mean=0.196 nm) and the kinetic diameter of helium and argon, the number of fused silica solubility sites available to helium exceeds the number of solubility sites available to argon. The total number of interstitial sites is estimated to be 2.2×10²⁸ per m³, with 2.3×10²⁷ helium solubility sites per m³ and 1.1×10²⁶ argon solubility sites per m³. The average distance between solubility sites for helium is considered to be 0.94 nm, while the average distance between solubility sites for argon is considered to be 2.6 nm. The structural channels connecting these solubility sites are thought to be similar to the helical arrangement of 6-member Si—O rings, with a diameter of about 0.3 nm. Table 1 summarizes some parameters affecting helium and argon permeability in fused silica.

TABLE 1
Selected properties of helium and argon.

| Property | Helium | Argon |
|---|---|---|
| Kinetic Diameter (nm) | 0.256 | 0.341 |
| Solubility Site Density (m⁻³) | 2.3 × 10²⁷ | 1.1 × 10²⁶ |
| Distance Between Solubility Sites | 0.94 | 2.6 |
| (nm) | | |
| Structural Channel Diameter | ~0.3 | ~0.3 |
| Connecting Solubility Sites (nm) | | |

Boiko et al., “Migration Paths of Helium in α-Quartz and Vitreous Silica from Molecular Dynamics Data,” Glass Physics and Chemistry 29 (2003): 42-48, which is incorporated by reference herein, describes behavior of helium in amorphous or vitreous silica. Within a solubility site, the helium atom vibrates at an amplitude allowed by the interstitial volume. The atom passes from interstice to interstice through channels, which may be smaller in diameter than the interstices.

The parameters listed in Table 1 indicate that argon permeability in fused silica may be very low or negligible at room temperature (i.e., the kinetic diameter of argon exceeds the fused silica channel size). Since the kinetic diameters of oxygen and nitrogen are larger than the kinetic diameter of argon, air may be substantially unable to permeate fused silica. On the other hand, helium may diffuse into and permeate fused silica. Thus, when a helium environment is used rather than ambient air for a nano-imprint process, helium trapped between the template and the substrate may be able to permeate a fused silica template.

The relative density of similar materials may be defined as a ratio of the density of the materials. For example, a relative density of spin on glass (SOG) (density ρ_{SOG}=1.4 g/cm³) with respect to fused silica (density ρ_{fused silica}=2.2 g/cm³) may be calculated as 100%×(ρ_{SOG})/ρ_{fused silica}, or 64%. Fused silica may be used as a reference material for other materials with oxygen-silicon bonds. For material used to form a porous layer in an imprint lithography template, a relative density of a material with respect to fused silica of at least about 50% or at least about 65% provides a porosity suitable to allow movement of gases through the material.

In some cases, porogens may be added to material used to form a portion of a template or a substrate to increase a porosity and pore size of the material. Porogens include, for example, organic compounds that may be vaporized, such as norbornene, α-terpinene, polyethylene oxide, and polyethylene oxide/polypropylene oxide copolymer, and the like, and any combination thereof. Porogens may be, for example, linear or star-shaped. Porogens and process conditions may be selected to form a microporous low-k porous layer, for example, with an average pore diameter of less than about 2 nm, thereby increasing the number of solubility sites for a range of gases. In addition, the introduction of porogens and the increased porosity may enlarge the structure channels connecting gas solubility sites. For pore sizes of about 0.4 nm or greater, helium permeability of a low-k film may exceed helium permeability of vitreous fused silica.

One method of removing gases 60 from the volume defined between substrate 12 and template 18 includes absorption of gases 60 through template 18. In some cases, as illustrated in FIG. 4, template 18 may be modified to include one or more layers formed on a base layer 62. For example, first layer 64 may be formed on base layer 62, and second layer 63 may be formed on first layer 64. When a template includes a base layer 62, a first layer 64, and a second layer 63, the first layer may be referred to as the intermediate layer, and the second layer may be referred to as the cap layer. When a template includes a base layer 62 and three or more additional layers, the top layer may be referred to as the cap layer and the layers between the base layer and the cap layer may be referred to as intermediate layers.

As noted above with respect to template 18, base layer 62 may be formed from materials including, but not limited to, fused silica, quartz, silicon, organic polymers, siloxane polymers, borosilicate glass, fluorocarbon polymers, metal, hardened sapphire, and the like, or any combination thereof. A cap layer, one or more intermediate layers, or any combination thereof may be a porous layer. As used herein, “porous layer” refers to a layer that is less dense and/or more porous than fused silica.

As used herein, a thickness of a cap layer is considered to be a thickness of the residual layer (i.e., not including the height of the protrusions). Gas may diffuse more quickly through portions of the cap layer from which there are no protrusions, achieving an overall increase in helium permeability. Thus, cap layers with thinner residual layers allow more rapid diffusion of gas through the cap layer and into the next (e.g., porous) layer. This diffusion rate depends at least in part on the fraction of the surface area of the template free from protrusions. Intermediate layers and cap layers may be formed by a vapor deposition process such as plasma enhanced chemical vapor deposition. Ranges of process variables for forming intermediate layers and cap layers are listed in Table 2 below.

TABLE 2
Example PECVD process variables for intermediate and cap layers.

| PECVD process variable | Cap layer | First layer/intermediate layer |
|---|---|---|
| N₂O:SiH₄ Ratio | 2-25 | 1-3 |
| Power Density (W/cm²) | 0.1-0.25 | 0.15-0.5 |
| Pressure (mTorr) | 300-1000 | 100-500 |
| Temperature (° C.) | 250-450 | Room temp. to 350 |

Porosities of the cap layer and the intermediate layer may be selected to facilitate transportation of gases 60 trapped between the substrate 12 and the template through the cap layer and into the intermediate layer. For example, a cap layer may be microporous, mesoporous, or a combination thereof. That is, the pores in the cap layer may be less than 2 nm in diameter (microporous) or between 2 nm and 50 nm in diameter (mesoporous). An intermediate layer may be microporous, mesoporous, or macroporous. That is, pores in an intermediate layer may be less than 2 nm in diameter (microporous), from 2 nm to 50 nm in diameter (mesoporous), or greater than 50 nm in diameter (macroporous). In some cases, an intermediate layer may have regions with different porosities. For example, an intermediate layer may have a microporous region and a mesoporous region. Porous layers are described in U.S. patent application Ser. No. 12/275,998, which is incorporated herein by reference.

Sizes of the pores in a porous cap layer or porous intermediate layer may be substantially uniform, or with a desired distribution. Pores may range from substantially closed to fully interconnected. In some cases, for a cap layer, a pore size or average pore size is at least about 0.4 nm, at least about 0.5 nm, or less than about 2 nm (e.g., less than about 1 nm, in a range between about 0.4 nm and about 1 nm, or in a range between about 0.4 nm and about 0.8 nm). For an intermediate layer, pore size or average pore size may be at least about 0.4 nm or at least about 0.5 nm (e.g., up to about 1 nm, up to about 2 nm, up to about 15 nm, up to about 30 nm, up to about 40 nm, up to about 50 nm, or larger than about 50 nm).

For template 18 with a cap layer of SiOₓ (thickness of about 10 nm and permeability P₁), template permeability may be adjusted by selecting porosity and pore size of one or more intermediate layers. The effect of the permeability and thickness of the intermediate layers(s) on the effective permeability of a multi-layer composite imprinting stack with a thickness of 310 nm is shown in Table 3.

TABLE 3
Intermediate layer properties for multi-layer composites.

| Cap Layer | Intermediate | | | | |
|---|---|---|---|---|---|
| Thickness | layer | Base Layer | | | Effective |
| (SiOₓ), | Thickness, | Thickness | | | Permeability |
| Permeability | Permeability | (SiO₂), | | Permeability | of the |
| P₁ | P₂ | Permeability P₁ | | Ratio | Total Stack |
| 10 nm | 300 nm | 0 | | P₂ = 1000 P₁ | 30.1 P₁ |
| 10 nm | 200 nm | 100 | nm | P₂ = 1000 P₁ | 2.8 P₁ |
| 10 nm | 100 nm | 200 | nm | P₂ = 1000 P₁ | 1.5 P₁ |
| 10 nm | 300 nm | 0 | | P₂ = 100 P₁ | 23.8 P₁ |

Table 3 suggests that increasing a thickness of the intermediate layer alone may yield a higher effective permeability than increasing the permeability of the intermediate layer alone. That is, for composite imprinting stacks with a total thickness of 310 nm and having an intermediate layer thickness of 100 nm, 200 nm, or 300 nm and a cap layer thickness of 10 nm, the effective permeability increases twenty-fold, from 1.5 P₁ to 2.8 P₁ to 30.1 P₁, respectively, over the 200 nm increase in intermediate layer thickness. For an intermediate layer thickness of 300 nm and a cap layer thickness of 10 nm, a ten-fold increase in permeability of the intermediate layer from 100 P₁ to 1000 P₁ increases the effective permeability from 23.8 P₁ to 30.1 P₁.

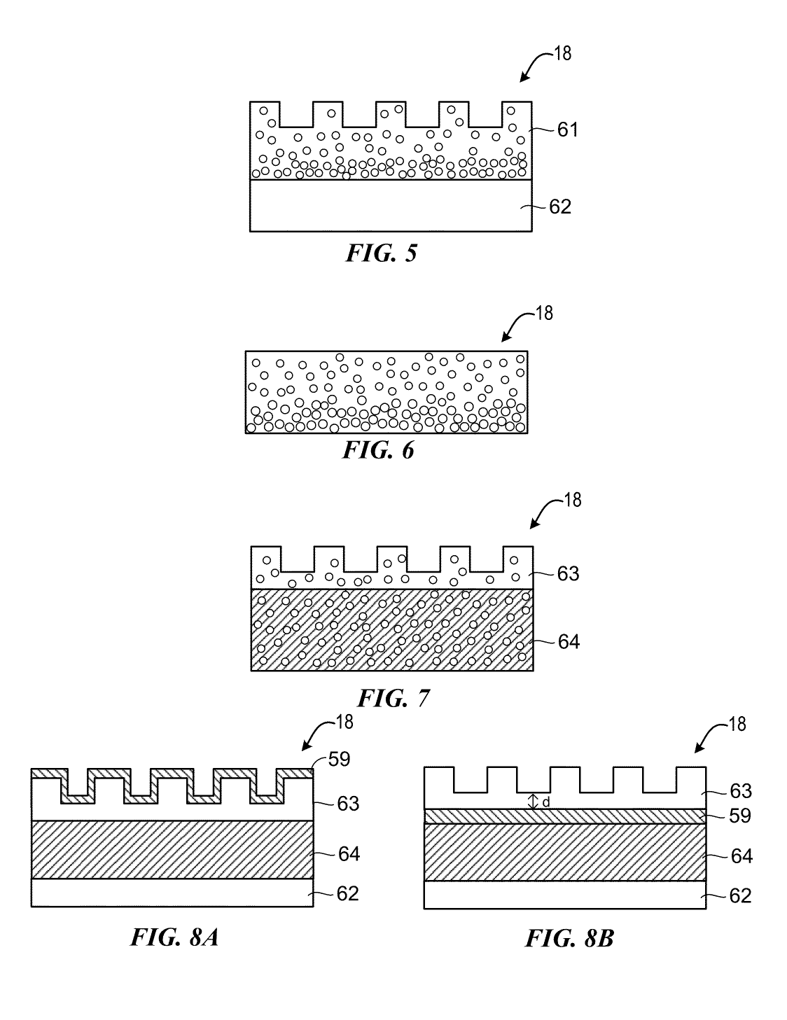

In some cases, as shown in FIG. 5, an imprint lithography template may include a base layer and a first layer. The first layer may be a porous layer. The first layer may be patterned, and may be thought of as a cap layer. Referring to FIG. 5, a porous layer 61 can be formed on a base layer 62. Porosity of the porous layer 61 may be non-uniform or asymmetric, as shown in FIG. 5, or substantially uniform. Porous layer 61 may be a cap layer. In some cases, porous layer 61 may have a porosity gradient, shown by the distribution of pores 65, such that the density of the layer is higher near the top surface of the layer (i.e., the surface in contact with the imprint resist during use). The porosity gradient may include changes in average pore size, pore size distribution, and/or pore density. The gradient may improve the mechanical strength of the features that are etched directly into the porous layer, while allowing diffusion of gases into the porous layer. That is, reduced porosity near the top of the cap layer (e.g., reduced porosity of the protrusions and proximate the protrusions) may yield a patterned portion with more mechanical strength than a cap layer with a higher porosity near the top of the cap layer. In some cases, the porous layer 61 may have a substantially uniform density in the portion of the layer that is etched to form the protrusions and recessions. The porous layer 61 may have microporous, mesoporous, or macroporous regions, or any combination thereof.

As shown in FIG. 6, a template 18 may be formed as a unitary structure with a porosity and average pore size selected to allow efficient diffusion of a gas while maintaining mechanical strength near the top of the cap layer. Templates made from, for example, organic polymers, inorganic materials (e.g., silicon carbide, doped silica, VYCOR®), and the like, or any combination thereof, may have a lower packing density, and therefore a higher gas (e.g., helium) permeability, than vitreous fused silica. Template 18 consists essentially of a single porous layer. The porous layer is not adhered to a base layer. Template 18 may be smooth or patterned. Template 18 may be an asymmetric porous layer, as shown in FIG. 6, or a symmetric porous layer.

As shown in FIG. 7, a template 18 may include a first layer 64 and a second layer 63. First layer 64 may be a porous layer. Second layer 63 may be a cap layer. As with template 18 in FIG. 6, the first layer is not adhered to a base layer. The second layer 63 may inhibit penetration of the polymerizable material into the porous material. The second layer 63 may also impart desirable surface properties, mechanical properties, and the like to the template. Template 18 may be smooth or patterned. First layer 64 may be an asymmetric porous layer.

Microporous layers may be advantageous in imprint lithography applications. For example, microporous layers may have pores large enough to allow diffusion of trapped gas through the pores, but small enough to inhibit penetration of the pores by polymerizable fluid or other substances. Microporous cap layers may have sufficient mechanical strength to withstand repeated use without cracking, buckling, or delaminating. Compared to patterned mesoporous and macroporous layers, patterned microporous layers may have smoother sidewalls and smaller void defects inside etched features.

In some cases, pores at a surface of a template (e.g., in a cap layer or other porous layer), if not sealed, may allow penetration of polymerizable fluid or other substances into the template, which may cause clogging of the pores or added stress during an imprinting process. If pores near a surface of a template are sufficiently small, sealing of the pores may not be needed to inhibit penetration of polymerizable fluid or other substances into the pores. In some cases, however, it is advantageous to seal or fill exposed pores (e.g., with a less porous silicon oxide layer) by using a thin film deposition method that produces substantially continuous, conformal, ultrathin gas-permeable films to inhibit disadvantageous penetration, clogging, saturation, and the like, of the template by polymerizable fluid or other substances. Pore sealing may be accomplished by a number of methods including, but not limited to, vapor-based film deposition processes such as chemical vapor deposition (CVD), atomic layer deposition (ALD), plasma-assisted atomic layer deposition (PA-ALD), pulsed plasma-enhanced chemical vapor deposition (pulsed-PECVD), molecular layer deposition (MLD), and physical vapor deposition (PVD), or by solution-based film deposition methods such as dip coating and spin coating, or plasma treatment. PA-ALD is described in US patent Application Publication No. US 2007/0190777, which is incorporated herein by reference. Pulsed-PECVD is described in U.S. Patent Application Publication No. 2008/0199632, which is incorporated herein by reference.

The selection of a seal layer deposition process and film composition can depend on several factors, including the size and/or geometry of template protrusions and recesses, the exposed pore diameter in the porous film, the desired permeability and mechanical properties of the seal layer, and the ability of the seal layer to interact with release agents, etc.

FIG. 8A shows a porous template 18 with a base layer 62, first intermediate layer 64, cap layer 63, and seal layer 59. Seal layer 59 may be made from materials including, but not limited to: metal oxides, nitrides, carbides, oxynitrides, oxycarbides, or polymers such as organo-silanes and polyxylylenes. A thickness of seal layer 59 on the surface of a porous layer may be less than about 10 nm, less than about 5 nm, less than about 3 nm, or, in some cases, about two times greater than the pore radius. In some cases, the pore sealing deposition method may be selected to substantially confine the reaction and growth of seal layer 59 to the surface of the porous layer. In certain cases, the seal layer reactants may be allowed to penetrate several nanometers into the porous layer.

Pore sizes in seal layer 59 may be larger than the kinetic diameter of the gas in the imprint environment to facilitate the diffusion of the gas into the adjoining porous layer. Pore sizes in seal layer 59 may be less than about 2 nm, less than about 0.8 nm, or less than about 0.6 nm, such that helium is able to diffuse through the seal layer. Seal layer 59 may be selected such that atoms or molecules larger than helium, oxygen, nitrogen, or carbon dioxide may be unable to diffuse through the seal layer. The material used to form seal layer 59 may be selected to withstand repeated use in nano-imprint lithography processes, including piranha, dilute base, ozone, or plasma cleaning processes. In some cases, seal layer 59 may be selected to be a non-permanent or sacrificial layer which is intended to be removed and replaced.

FIG. 8B illustrates a porous template 18 with a base layer 62, porous intermediate layer 64, seal layer 59, and cap layer 63. The seal layer preferably has pores large enough for helium to pass through, but small enough to substantially block reactive species in vapor or liquid phase from penetrating the porous layer during cap layer deposition. Seal layer 59 may have a thickness of about 1 nm to about 10 nm, or less than about 5 times the pore radius, less than about 3 times the pore radius, or about two times the pore radius. Seal layer 59 may include, for example, silicon oxide (SiOₓ). In some cases, rather than seal the surface pores completely with a continuous film, a seal layer process may be used to decrease the open pore size of the porous layer such that diameters of the pores inhibit the penetration (e.g., diffusion) of cap layer components into the porous layer.

The presence of the seal layer beneath the cap layer (e.g., between the cap layer and the porous layer) allows a clear transition from the cap layer to the porous layer, and inhibits penetration of pore-clogging contaminants into the porous layer. For example, seal layer 59 may inhibit penetration of reactive species present during formation of the cap layer 63 into porous layer 64. Penetration and pore clogging of the porous layer increases the density of the porous layer near the interface between the porous layer and, for example, the cap layer, and thus makes it difficult to ascertain the location of the interface during etching. The presence of a seal layer below the cap layer would maintain the integrity of the interface, and reduce or substantially eliminate ambiguity as to the required etch depth of the features in the cap layer. Thus, the deposition of a seal layer on the porous layer enables the etch process, because it is advantageous to have as little cap layer material between the bottom of the feature and the porous layer underneath. This distance is indicated by d in FIG. 8B.

In an example, a porous layer is deposited on a base layer. A thin (e.g., 5 nm), dense pore seal layer is formed on the porous layer, and a dense cap layer (95 nm) is formed on the seal layer. The total thickness of the dense coating is 100 nm. If the cap layer is etched to a depth of 90 nm, then d=10 nm, and 10 nm of dense film separates the bottom of the feature from the underlying porous film. In the absence of a seal layer, several nanometers of the porous layer may have become blocked and the film density profile may vary with depth, all of which make it more difficult to determine how far to etch features in to the cap layer so that the features reside in a uniformly dense film with a known distance to the porous layer underneath. Some methods of pore sealing include ALD, PA-ALD, and pulsed PECVD, as well as other methods mentioned herein. Use of a method such as ALD to form the cap layer as well as the seal layer would limit throughput and increase production costs.

As described herein, a pore seal layer may allow optical thickness measurements of the cap layer if the refractive index of the seal layer differs from the refractive index of the cap layer. For example, a cap layer may be deposited on top of the seal layer and then polished back to a known measurable distance from the seal layer.

In some cases, a less porous seal layer and a cap layer may be deposited on a more porous layer (e.g., intermediate layer) at temperatures less than, equal to, or greater than that used for deposition of the more porous layer. Although the less porous layer may be deposited at a higher temperature than that used for the more porous layer beneath it, it may be desirable in some cases to deposit the less porous layer at a temperature equal to or less than the deposition temperature of the more porous layer if thermal effects during the less porous layer deposition induce undesirable changes to pore size, pore size distribution, pore interconnectivity, and the like in the more porous layer.

The material used to form a porous cap layer or a porous intermediate layer may be selected to withstand repeated use in nano-imprint lithography processes, including piranha, dilute base, and ozone, or plasma cleaning processes. In some cases, a porous cap layer or a porous intermediate layer may be designed for limited use, and may not need the ability to withstand a cleaning process. Adhesion of an intermediate layer to a base layer and to a cap layer may be, for example, at least about three times the force required to separate the template from the patterned layer formed in an imprint lithography process. Material properties to be considered in selection of porous materials include adhesion to the base layer, coefficient of thermal expansion, thermal conductivity, refractive index, and UV light transmittance and absorbance. For example, a material with low UV absorbance allows UV radiation to pass through a cap layer or an intermediate layer of a template to polymerize the imprint resist without generating a disadvantageous amount of heat proximate the imprint resist. In certain embodiments, Young's modulus of the porous material may be, for example, at least about 2 GPa, at least about 5 GPa, at least about 10 GPa, or at least about 20 GPa.

In some applications, a template will be required to make hundreds or even thousands of imprints before it has satisfied its cost of ownership objective. Therefore, materials used for the porous layer must have sufficient mechanical strength to survive this number of imprints without cracking, buckling, or delaminating. A porous material with a selected Young's modulus, in combination with a selected relative density and refractive index may be used to form a porous layer with unexpected advantages, including a decrease in filling time, allowing high-throughput in a fabrication process, and a simultaneous ability to withstand mechanical forces present during the imprinting process. This combination of desirable properties allows increased process longevity and low template defectivity.

The ratio of the Young's modulus of a porous material including silicon and oxygen to the relative density of that material with respect to fused silica, is an indicator of the ability of a porous material to perform as a porous layer in an imprint lithography template. A porous silicon- and oxygen-containing material that provides desirable throughput and durability may have a ratio of Young's modulus to relative density of the material with respect to fused silica of at least about 10:1, at least about 20:1, or at least about 30:1.

Optical-based processes related to imprint lithography templates include, for example, optical-based template pattern inspection. To facilitate optical-based processes, the refractive index of a porous layer may be similar to the refractive index of other layers in the template (e.g., cap layer, seal layer) on the same template, such that unwanted optical effects (e.g., bending of light and related distortion) are reduced during processes including measurement processes and inspection processes. The refractive index for fused silica is 1.46. When fused silica is used as a base, it may be desirable for other layers of an imprint lithography template to have a refractive index close to that of fused silica. For increased optical compatibility with other layers in an imprint lithography template, the refractive index of a porous layer in an imprint lithography template may be between about 1.4 and about 1.5.

A porous layer (e.g., a porous intermediate layer) may be made from materials including, but not limited to, silicon oxide, anodic aluminum oxide (AAO), organo-silanes, organo-silicas, organosilicates, organic polymers, inorganic polymers, and the like, or any combination thereof. In some embodiments, a porous layer may include low-k, porous low-k, or ultra-low-k dielectric film. Low-k dielectric films used in the semiconductor industry, i.e. organosilicate glass (OSG) films deposited by CVD of organosilanes or by spin-coating of silsesquioxanes, may contain sufficient porosity to enhance gas diffusion and decrease filling time, however their mechanical properties (elastic modulus, E<10 GPa; hardness, H<2 GPa) are poorer than fused silica. Porous layers including organic or inorganic polymers are also have much lower mechanical properties compared to fused silica. Anodic aluminum oxide (AAO) films have higher Young's modulus (˜140 GPa) than fused silica with high porosity, but also have a higher refractive index compared to fused silica (˜1.7 vs. 1.46), thus in this regard AAO may be less desirable as a porous layer when capped with a silicon oxide film when optical pattern inspection is considered.

A base layer and an intermediate layer or a cap layer may be formed of the same or different materials. In some cases, a cap layer may be more porous than base layer (e.g., to allow gases to diffuse through the cap layer and into an intermediate layer). In some cases, a cap layer may be less porous than intermediate layer (e.g., to facilitate successful etching of the cap layer to form a desirable patterned surface). In some embodiments, the cap layer is more porous than the base layer and less porous than the intermediate layer. A cap layer may be formed by material selected to achieve desirable wetting and release performance during an imprint lithography process.

In some embodiments, a cap layer may include a film of porous SiOₓ with 1≦x≦2.5. For example, as used herein, “porous SiOₓ” refers to silicon oxide that is more porous than fused silica, less dense than fused silica, or both. A thickness and composition of the cap layer may be chosen to provide mechanical strength and selected surface properties, as well as permeability to gases that may be trapped between a substrate and a template in an imprint lithography process.

A thickness of an intermediate layer may be, for example, in a range of about 10 nm to about 100 μm, or in a range of about 100 nm to about 10 μm. A thickness of an intermediate layer may be increased to increase the capacity of the layer to accommodate diffusion of gases into the layer. In some cases, a thicker intermediate layer may provide higher effective permeability without significantly reducing UV transparency, thermal expansion, and the like.

A thickness of a cap layer may be in a range of about 10 nm to about 10,000 nm (e.g., in a range of about 10 nm to about 50 nm, about 50 nm to about 100 nm, about 100 nm to about 500 nm, about 500 nm to about 1000 nm, or about 1000 nm to about 10,000 nm). Diffusion of gas through a cap layer is related to the porosity of the cap layer as well as the thickness of the cap layer. In some cases, a thickness of a cap layer may be selected based at least in part on the porosity of the cap layer. That is, a more porous cap layer may be thicker (e.g., about 5000 nm) than a less porous cap layer (e.g., about 10 nm), such that gas can diffuse relatively quickly through porous cap layers of various porosities and thicknesses. If a cap layer is more porous than the layer to which it is adhered, a thickness of a cap layer may be increased to increase the capacity of the layer to accommodate diffusion of gases into the layer. If the cap layer is adhered to a more porous film, then it may be desirable to decrease the thickness of the cap layer between the bottom of an etched feature and the more porous layer to decrease diffusion resistance.

An intermediate layer may be formed by vapor deposition, solution-based methods, thermal growth methods, or the like on a base layer or on another intermediate layer. A cap layer may be formed by vapor deposition, solution-based methods, thermal growth methods, or the like on an intermediate layer or a base layer. As used herein, “vapor deposition” generally refers to a process in which a layer is formed from a vaporized precursor composition on a surface of a substrate. Vapor deposition processes include, but are not limited to, chemical vapor deposition (CVD), atomic layer deposition (ALD), and physical vapor deposition (PVD). CVD processes include, for example, plasma-enhanced CVD (PECVD), low-pressure CVD (LPCVD), sub-atmospheric CVD (SACVD), atmospheric pressure CVD (APCVD), high density plasma CVD (HDPCVD), remote plasma CVD (RPCVD), and the like. PVD processes include ion-assisted e-beam methods, and the like.

By varying the process conditions and materials, porous layers with different mean pore sizes and pore size distributions (e.g., different porosity or relative porosity) may be produced. An intermediate layer and/or a cap layer may have pores with a larger pore size and a greater porosity than fused silica. As used herein, “porosity” refers to the fraction, as a percent of total volume, occupied by channels and open spaces in a solid. The porosity of an intermediate layer may range from about 0.1% to about 60% (e.g., about 1% to about 20%, or about 5% to about 15%). In some cases, the porosity of an intermediate layer may be at least about 10%, or at least about 20%. The porosity of a cap layer may range from about 0.1% to about 20% (e.g., from about 1% to about 20%, or from about 3% to about 15%).

Depositing SiOₓ by a vapor deposition process (e.g., PECVD) can yield a film with higher porosity than other processes such as thermal oxidation or flame hydrolysis deposition. Vapor deposition conditions that can be varied include temperature, pressure, gas flow rates (e.g., for the silicon-containing gas, the oxidation gas, the carrier gas, etc., or ratios thereof), electrode distance, RF power, and bias.

In an example, oxide deposition from silane-PECVD can occur according to the reaction shown below:

SiH_{4(g)}+2N₂O_{(g)}→SiO₂₍ₛ₎+2N_{2(g)}+2H_{2(g)}.

Organosilicon materials such as tetraethyl orthosilicate (TEOS), tetramethylsilane (TMS), and hexamethyldisilazane (HMDS) may also be used with PECVD to form SiOₓ films.

The density of PECVD SiO₂ has been shown by Levy et al. (“A comparative study of plasma enhanced chemically vapor deposited Si—O—H and Si—N—C—H films using the environmentally benign precursor diethyl silane,” Mater. Lett. 54 (2002): 102-107, which is incorporated herein by reference), to vary from 1.5 g/cm³ to 2.2 g/cm³ at deposition temperatures between 100° C. and 350° C. The Young's modulus increased from 25 GPa to over 70 GPa over this temperature range. PECVD has been reported to generate silicon oxide films with a Young's modulus as high as 144 GPa at deposition temperatures of 250° C. to 350° C. (Bhushan et al., “Friction and wear studies of silicon in sliding contact with thin-film magnetic rigid disks,” J. Mater. Res. 9 (1993) 1611-1628; and Li et al., “Mechanical characterization of micro/nanoscale structures for MEMS/NEMS applications using nanoindentation techniques,” Ultramicroscopy 97 (2003) 481-494, both of which are incorporated by reference herein).

A Young's modulus of 25 GPa is substantially higher than the Young's modulus of films obtained from porous semi-conductor low-k films, including organosilicate glass films deposited by CVD of organosilanes or by spin-coating of silsesquioxanes. The hardness of a PECVD SiOₓ film deposited at temperatures greater than about 150° C. may also exceed the hardness of a semi-conductor low-k film. A PECVD SiOₓ film deposited at about 350° C. may have about 5% microporosity, as described by Devine et al. (“On the structure of low-temperature PECVD silicon dioxide films,” J. Electron. Mater. 19 (1990) 1299-1301, which is incorporated by reference herein).

SiOₓ deposited on a fused silica substrate by PECVD displays compressive stress believed to originate at least in part from a mismatch of coefficients of thermal expansion. This mismatch may be reduced by thermal annealing at moderate temperatures (e.g., a 500° C. thermal cycle), as described by Cao et al. (“Density change and viscous flow during structural relaxation of plasma-enhanced chemical-vapor-deposited silicon oxide films,” J. Appl. Phys. 96 (2004) 4273-4280, which is incorporated herein by reference). With selected annealing conditions, the nature of the stress may become more tensile in nature, while still maintaining a compressive to neutral stress desirable for a porous layer in an imprint lithography template. As shown by Cao et al., the coefficient of thermal expansion of a 10 μm thick PECVD SiOₓ film after a 500° C. thermal cycle (about 0.55 ppm/° C.) is similar to that of fused silica.

In some cases, annealing of a PECVD SiOₓ template layer may promote densification of the SiOₓ film, resulting in lower permeability. However, an annealing process carried out at lower temperatures (e.g., about 100° C. to about 350° C.) under controlled conditions (e.g., heating and cooling rates) may maintain the porosity of the film.

Low temperature annealing experiments were carried out to evaluate the impact of annealing on film stress. As shown in Table 4, a PECVD SiOₓ film (thickness of 5 μm) on fused silica had a calculated stress of −94 MPa after deposition. Following a first 140° C. annealing cycle, the stress was calculated as −57 MPa. Following a second 140° C. annealing cycle, the stress was calculated as −42 MPa. The stress was calculated by the Stoney equation. Radii were determined by measurements with a laser interferometer (Mark GPI xps, available from Zygo Corporation, Middlefield, Conn.), and film thickness was measured with a spectroscopic reflectometer (available from Metrosol, Austin, Tex.).

TABLE 4
Calculated stress of PECVD SiO₂ film on fused silica.

| Sample | Calculated Stress |
|---|---|
| As deposited 5 μm PECVD SiO₂ film | −94 MPa |
| After first 140° C. annealing cycle | −57 MPa |
| After second 140° C. annealing cycle | −42 MPa |

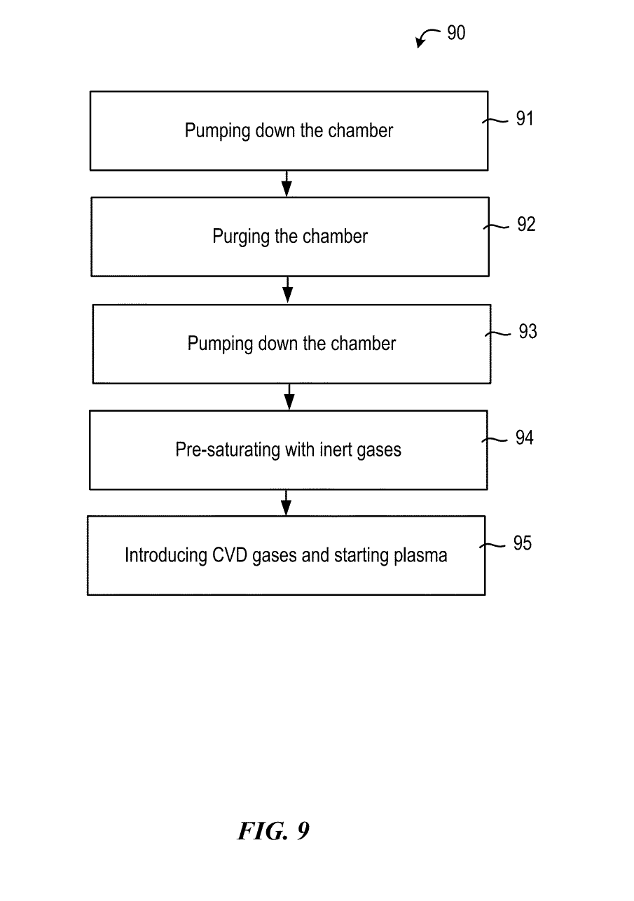

In some cases, forming a cap layer (e.g., a SiOₓ cap layer) with a vapor deposition process on an intermediate layer may clog pores in the intermediate layer. To reduce clogging of pores in the intermediate layer, the intermediate layer may be pre-saturated with inert gas. An exemplary PECVD process to reduce clogging of pores in a porous substrate is shown in the flow chart in FIG. 9. In process 90, after pumping the chamber (step 91), purging the chamber (step 92), and pumping the chamber again (step 93), one or more inert gases are used to pre-saturate the chamber and the porous substrate (step 94). The flow of inert gases is stopped, and the CVD gases are introduced to the chamber and the plasma is started (step 95).

In process 90, the CVD layer is thought to grow from the surface of the intermediate layer for several reasons. For example, since the pores have been saturated by inert gases, it is difficult for CVD gases to diffuse into the intermediate layer. Additionally, even though some of the CVD gases may get into the porous intermediate layer, they are diluted with the inert gases inside the intermediate layer and may not be present in sufficient quantity to form a dense structure capable of blocking the pores after reaction. Furthermore, since the plasma starts at substantially the same time as the CVD gases are introduced into the chamber, the reaction starts right away, and the CVD gases have limited time to diffuse into the intermediate layer.

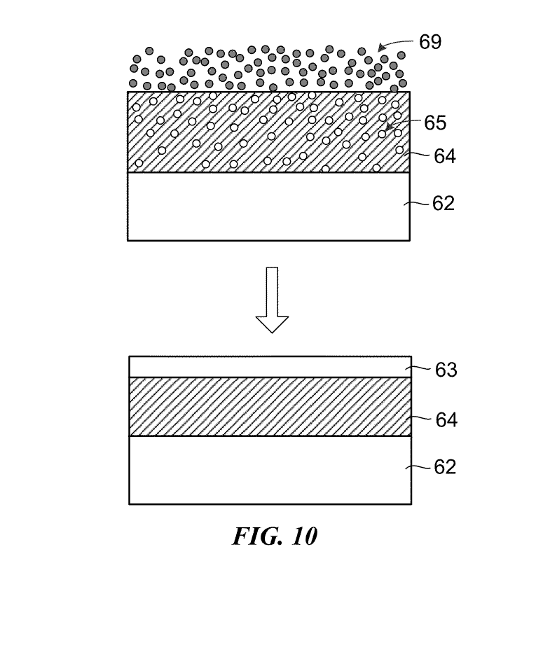

FIG. 10 illustrates a process of capping a porous first layer 64 (e.g., an intermediate layer) with a thin layer of vapor deposited SiOₓ as a second layer 63 (e.g., a cap layer) according to the steps in FIG. 9. This process could also be applied in the sealing of a cap, or the sealing of an asymmetric porous layer. As shown in FIG. 10, porous first layer 64 is saturated with inert gas 65. Gas 69 (including silicon-containing gas, oxidation gas, carrier gas, etc.) is introduced in a CVD process to form silica second layer 63 on porous first layer 64. After second layer 63 is formed on the surface of porous first layer 64, the porous first layer will be effectively sealed, such that diffusion of the vapor deposited gases, polymerizable material, and the like, into the porous first layer is reduced or eliminated.

The gases used for pre-saturation may be inert toward selected vapor deposition processes or may not react inside the porous layer to clog the pores. The inert gas may be helium, neon, argon, or nitrogen, or the like. In some cases, the vapor deposition gas may be used as the inert gas. For example, in a PECVD SiOₓ deposition process with SiH₄ and N₂O, N₂O may be used to pre-saturate a porous layer. Smaller molecule gases such as helium and neon may diffuse out after the process if their kinetic diameters are smaller than the pore size of the seal layer. Larger molecule gases such as argon and nitrogen might be trapped inside the a porous layer if their kinetic diameters are larger than the pore size of the seal layer. Gases trapped inside the porous layer may cause complications in future applications. Therefore, smaller molecule gases may be preferred.

Pre-saturation 91 in process 90 may range from about 5 seconds to about 60 min. The inert gas pressure may be at least the same as the total vapor deposition gas pressure used for the vapor deposition process and in some cases higher than the total vapor deposition gas pressure. An initial deposition rate might be slightly slower due to the dilution effect by the inert gases. To achieve more precise vapor deposition layer thickness control, the deposition rate may be re-calibrated between procedures. Different inert gases may result in different initial deposition rates. The deposition rate may to be re-calibrated when changing to a different inert gas. Different inert gas pressure may also result in a different initial deposition rate. The deposition rate may be re-calibrated when changing to a different pre-saturation pressure.

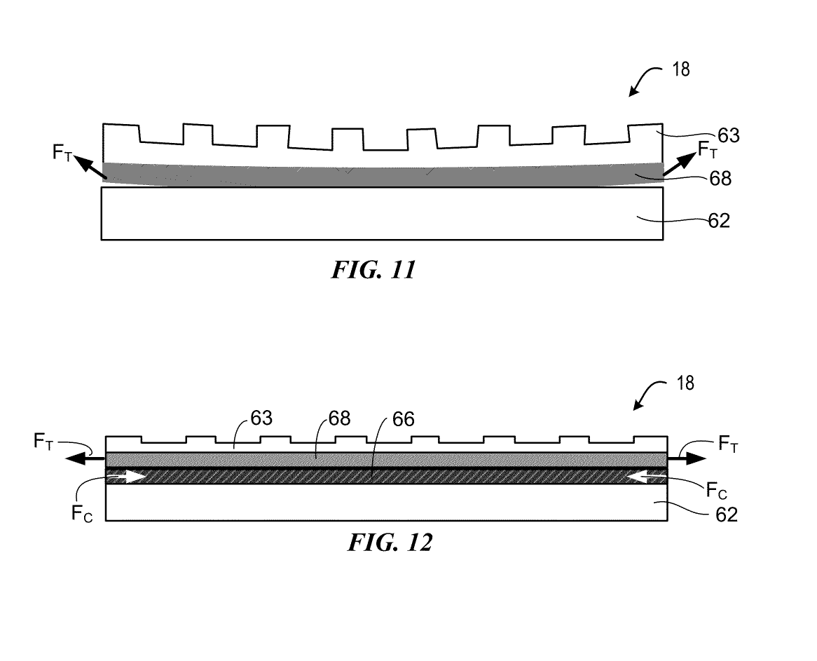

In certain circumstances, a porous layer may be subject to internal tensile stress that leads to cracking or delaminating of the film. As illustrated in FIG. 11, porous layer 68 may be subject to intrinsic forces that produce a tensile force F_{T} (or compressive force F_{C}) affecting the porous layer. For example, tensile force F_{T} (or compressive force F_{C}) may result in separation of porous layer 68 from base layer 62, angular deformation, and the like.

The stress in a porous layer or film at ambient conditions (e.g., room temperature, atmospheric pressure) may be tensile to compressive (e.g., about +1 GPa to about −3 GPa, respectively). The stress of a vapor deposited porous layer may be managed by a number of methods, such as control of deposition conditions, annealing, or stress relief films or layers.

Template 18 may include one or more relief layers 66 designed to mitigate the effects (e.g., template curvature) of tensile force F_{T} acting on porous layer 68. For example, relief layer 66 may be designed having materials formed in a compressive state such that compressive force F_{C} acts on relief layer 66. For example, relief layer 66 may be designed from materials providing a set intrinsic stress level resulting in compressive force F_{C}. As such, compressive force F_{C} acting on relief layer 66 substantially neutralizes the tensile force F_{T} acting on porous layer 68 within template 18. In some embodiments, one or more relief layers 66 may be designed to mitigate the effects of compressive force F_{C} (not shown) acting on porous layer 68.

For example, FIG. 12 illustrates an exemplary embodiment of template 18 having porous layer 68 adjacent to relief layer 66. Relief layer 66 may be formed of materials providing a compressive force F_{c} such that compressive force F_{c} substantially reduces the effects of tensile force F_{T} acting on porous layer 68. Relief layer 66 may be positioned on substrate layer 62 using techniques such as spin-coating, dip coating, CVD, PVD, thin film deposition, thick film deposition, or the like, or any combination thereof. The relief layer 66 may be formed of material including, but not limited to SiNx, SiOxN_{y}, SiCₓ, SiOₓ, DLC, and the like, or any combination thereof. In some cases, relief layer 66 may be substantially transparent to UV light or wavelengths of light used during the imprint process. Relief layers 66 may be permeable to gases such as helium, nitrogen, oxygen, carbon dioxide, and the like. In some embodiments, one or more relief layers 66 may be designed to provide a tensile force F_{T} such that tensile force F_{T} substantially reduces the effects of compressive force F_{C} (not shown) acting on porous layer 68.

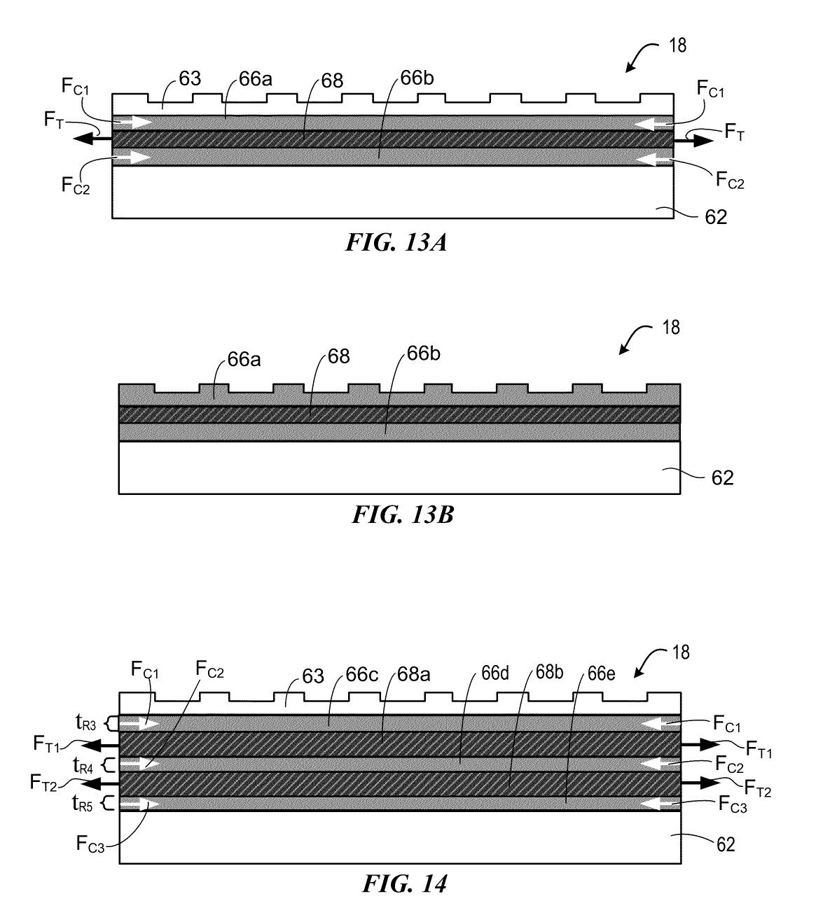

FIG. 13A illustrates an exemplary embodiment of template 18 having multiple relief layers 66a and 66b adjacent porous layer 68. Porous layer 68 may be permeable to gases such as helium, nitrogen, oxygen, carbon dioxide, and the like. Relief layers 66a and 66b may be formed of materials providing compressive forces F_{C1} and F_{C2}. Compressive forces F_{C1} and F_{C2} may be similar or different in magnitude, depending on design considerations. For example, compressive force F_{C2} of relief layer 66b may reduce the effects of tensile force F_{T} on porous layer 68 (e.g., may reduce bending of the layer).

Relief layers 66a and 66b may be positioned on substrate layer 62 and porous layer 68, respectively, using techniques such as spin-coating, dip coating, chemical vapor deposition (CVD), physical vapor deposition (PVD), thin film deposition, thick film deposition, or the like, or any combination thereof. Relief layers 66a and 66b may use similar positioning methods or different positioning methods depending on design considerations.

Additionally, relief layers 66a and 66b may be formed of similar materials or different materials depending on design considerations. For example, as relief layer 66a may be positioned within the diffusion path of gases 60 (not shown), relief layer 66a, having a thickness t_{R1}, may be formed of materials permeable to gases 60 present during the imprint process. Alternatively, relief layer 66b may have a thickness t_{R2} that is greater than thickness t_{R1} and may be formed of less permeable materials as the majority of stress compensation may occur at relief layer 66b. Additionally, relief layer 66b may be formed of permeable material to facilitate diffusion of gases into substrate layer 62, depending on design considerations. In some embodiments, as illustrated in FIG. 13B, relief layer 66a may be a patterned relief layer 66a having features 24 and 26 formed therein. In some embodiments, relief layers 66a and 66b may be formed of materials providing tensile forces F_{T1} and F_{T2} to reduce the effects of compressive force F_{C} (not shown) on porous layer 68.

FIG. 14 illustrates an exemplary embodiment of template 18 having multiple relief layers 66 to relieve tensile stress within multiple porous layers 68. In particular, template 18 comprises relief layers 66c-e that may be interspersed between permeable layers 68a and 68b such that compressive forces F_{C1-C3} reduce the effect of (e.g., the bending moments caused by) tensile forces F_{T1-T2}. Relief layers 66c-e may use similar positioning methods or different positioning methods depending on design considerations. Additionally, relief layers 66c-e may be formed of similar materials and have similar physical characteristics (e.g., thickness) and/or different materials and physical characteristics depending on design considerations. An analogous embodiment may provide relieve of compressive stress F_{C1-C3} caused by tensile forces F_{T1-T2} (not shown).

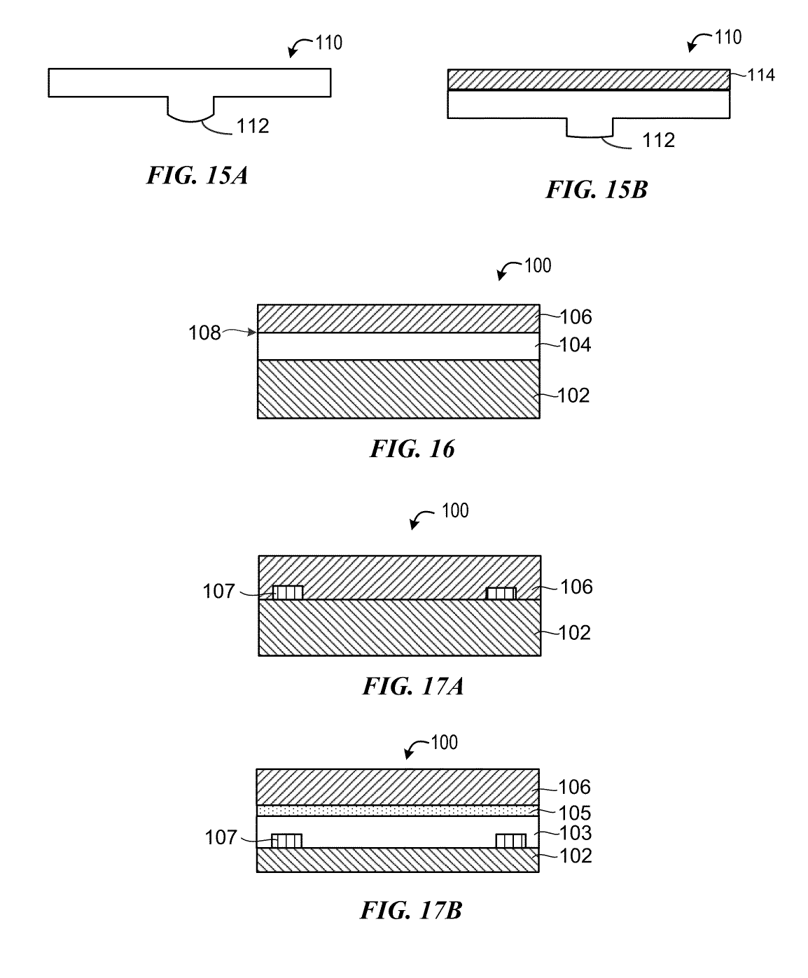

Referring to FIG. 15A, template 110 shows stress indicated as bending of layer or film 112 on the imprinting surface of the template. Referring to FIG. 15B, stress relief layer 114 is formed on the surface of template 110 opposite layer 112. Stress relief layer 114 relieves the stress in layer 112 by providing a bending moment which reduces the curvature of the layer. In some embodiments, stress relief layer 114 may provide compressive stress to reduce compressive stress of layer 112. In some embodiments, stress relief layer 114 may provide tensile stress to reduce tensile stress or to impart a compressive stress to layer 112.

### Etch Stop Layer

Referring to FIG. 16, template 100 includes a base layer 102, an etch stop layer 104, and a top layer 106. Etch stop layer 104 and top layer 106 differ with respect to certain physical properties (e.g., index of refraction), such that interface 108 between the etch stop layer and the top layer can be used as a reference point during nano-imprint lithography fabrication processes that include etching or chemical mechanical planarization (CMP) of the top layer. Etch stop layer 104 and top layer 106 also differ with respect to certain chemical properties (e.g., reactivity with known etching processes).

Template 100 may be, for example, bulk fused silica. Etch stop layer 104 may be substantially UV transparent and have low UV absorbance. In an example, etch stop layer 104 may include a metal, a metal oxide, or a metal nitride. In some cases, etch stop layer 104 consists essentially of SiₓN_{y}. Top layer 106 may be porous (e.g., porous silica). In some cases, top layer 106 includes SiOₓ, with 1≦x≦2.5.

The different physical characteristics of the etch stop layer 104 and the top layer 106 (e.g., different indices of refraction) allow optical/metrological assessment of the thickness of the top layer, as measured with respect to the interface 108 between etch stop layer 104 and top layer 106. Because a depth of top layer 106 can be accurately and precisely measured with respect to etch stop layer 104, top layer 106 can be polished back (e.g. with chemical mechanical planarization) to a known measurable distance from the etch stop layer 104 to enable etching processes in nano-imprint lithography template fabrication used to pattern top layers with known and reproducible dimensions (e.g., residual layer thickness, protrusion height, aspect ratio, and the like).

Etching processes that etch top layer 106 but not etch stop layer 104 may include any etching process that is known to etch silica (e.g., reactive ion etching). Thus, the different chemical properties of the etch stop layer 104 and the top layer 106 allow etching of the top layer without etching of the etch stop layer. The presence of etch stop layer 104 allows the top layer 106 to be completely removed by etching while leaving the etch stop layer and the base layer substantially unaltered. Thus, top layer 106 can be removed, changed, or replaced, as desired. The ability to reuse the base layer of the template is economically advantageous, and allows conservation of resources.

### Metrology Marker

In some cases, a region of a base layer or intermediate layer of an imprint lithography template may be coated with a marker film. FIG. 17A illustrates an imprint lithography template 100 with base layer 102, top layer 106, and marker region 107 formed at an interface between the base layer and the top layer. Marker region 107 may cover a small portion of the base layer 102 (e.g., less than about 1 cm²). A thickness of marker region 107 may be between about 2 nm and about 30 nm, such that a flatness of the upper surface of the top layer is substantially unaffected by the presence of the marker region. In some cases, top layer 106 may be polished smooth and flat (e.g., with chemical mechanical planarization) before patterning and etching features on the template. A thickness of marker region 107 may be used as a reference to determine a depth of etching of top layer 106. The material used to form marker regions 107 may include, for example, a metal, a metal oxide, or a metal nitride.

One or more marker regions 107 may be spaced apart from an active (e.g., patterned) portion of the top layer 106. Placing a metrology marker outside the mesa (e.g., placing four markers outside the corners of the mesa) would allow UV radiation to pass through the template and into the polymerizable fluid without blocking, and would reduce the total amount of radiation absorbed (and thus the amount of heating of the template) compared to a continuous etch stop layer.

In some cases, rather than depositing a small marker region, one or more areas of a template may be masked during coating of a base layer or coating of an intermediate layer with another layer (e.g., a porous layer). A difference in height between the masked area 109 and the coated portion 111 may serve as a reference for coating depth, etching depth, or polishing depth.

FIG. 17B illustrates a nano-imprint lithography template with marker regions 107 deposited on base layer 102. Porous layer 103 is formed over base layer 102 and marker regions 107. Porous layer 103 may be polished before seal layer 105 is deposited on the porous layer. The seal layer may inhibit clogging of the porous layer during formation of cap layer 106. That is, during formation of cap layer 106, the presence of the seal layer may inhibit infiltration and thus clogging of the porous layer with components (e.g., reactive species) used to form the cap layer. In some cases, based on the properties of porous layer 103 and the cap layer 106, the seal layer 105 may be omitted.

### Chemical Mechanical Planarization

In embodiments discussed herein, a layer of a template (e.g., a cap layer, an intermediate layer) may undergo chemical mechanical planarization (CMP). CMP includes the polishing of one or both sides of a substrate simultaneously, using both chemical and mechanical means. An imprint lithography template is held in a carrier housing. Slurry is dispensed on a polishing pad. The template is rotated and oscillated (eccentric motion) and is brought into contact with a rotating polishing pad. The force of the substrate against the pad is controlled. The slurry both reacts with the surface (chemical aspect of CMP) and physically scrubs the surface (mechanical aspect of CMP). The abraded material is carried away by the polishing pad

Surfaces formed by some PECVD processes, such as silicon oxide film deposition, may be undesirably rough. The roughness reduces the usefulness and desirability of these surfaces for use as an imprint surface for patterning, or for use as a base layer for the deposition of a conformal film. CMP can be used to polish a rough layer to substantially eliminate the roughness and improve flatness and parallelism of the template. CMP may also improve filling speed by reducing a roughness of a layer that contacts the imprint resist.

### EXAMPLES

### Example 1

The enhanced diffusion performance of low-temperature PECVD SiOₓ was shown through imprint testing. Samples for imprint filling tests were generated by depositing porous silicon oxide by PECVD (PlasmaTherm 790 RIE/PECVD) at 200° C. to a thickness of 5 μm on double-side polished (DSP) 3″ silicon wafers having a nominal thickness of 375 μm. The Si source was SiH₄, with a flow rate of 21.2 sccm. The oxidizing agent was N₂O, with a flow rate of 42 sccm. The deposition total pressure was 300 mTorr, and the RF power was 50 W. The wafer was placed directly on the chuck for deposition. The wafers were then spin-coated with 60 nm of TranSpin™ (available from Molecular Imprints, Inc., Austin, Tex.). As a control, a 3″ DSP silicon wafer was coated with 60 nm of TranSpin™. A 65 mm fused silica core-out template was used to generate imprints with a residual layer thickness of about 90 nm using a grid drop pattern with a 340 μm drop center-to-center distance. Helium was used as the purge gas.

### Example 2

FIGS. 18A and 18B show images of drops of imprint resist 180 in a helium environment taken through a template including a 5 μm porous silicon oxide cap layer formed on the wafer by PECVD. As shown in FIG. 18A, drop interstitial regions 182 were observed by a microscope camera at the time the template contacted the resist. The image in FIG. 18B was taken 1 second after the template contacted the resist. Within 1 second after the resist was contacted by the template, gas pockets in the interstitial locations 182 disappeared, and imprint resist 180 spread to substantially cover the template.

FIGS. 19A-19C show images of drops of imprint resist 180 in a helium environment taken through a template similar to that in FIG. 18A, without the 5 μm porous silicon oxide cap layer. FIG. 19A shows drops of imprint resist 180 and interstitial regions 182 as observed by a microscope camera at the time the template contacted the resist. FIGS. 19B and 19C show interstitial regions 182 still present 1 second later and 4 seconds later, respectively. Thus, the porous oxide layer allowed for the quick uptake of helium, which resulted in the void filling more than 4 times faster than the same void on an imprint made on a silicon wafer without the porous silicon oxide layer.

### Example 3

Table 5 lists PECVD process conditions for the formation of four silicon oxide layers and a thermal oxide layer. Films were grown on DSP 3″ silicon wafers to 1.5 μm thickness in a PlasmaTherm 790. Due to the fixed-position chuck of the PlasmaTherm 790, the silicon wafers were placed on top of a 3.5″ diameter×0.25″ polished fused silica plate instead of directly on the chuck in order to better approximate the growth conditions for a 0.25″ thick fused silica template. Indentation hardness and modulus of the PECVD silicon oxide films were measured on a CSM Instruments NHTX nanoindentation tester with an indentor of Berkovich geometry. PECVD silicon oxide film density was measured by X-ray spectroscopy (XRR).

TABLE 5
Example PECVD Process Conditions.

| | | | | | | | Indentation | Indentation |
|---|---|---|---|---|---|---|---|---|
| | N₂O | SiH₄ | Power | Pressure | Temp | Density | Modulus | Hardness |
| Sample | (sccm) | (sccm) | (W) | (mTorr) | (° C.) | (g/cc) | (GPa) | (GPa) |
| 1 | 42 | 21.2 | 50 | 300 | 270 | 1.83 | 49.6 | 4.8 |
| 2 | 42 | 21.2 | 50 | 300 | 300 | 1.96 | Not | Not |
| | | | | | | | measured | measured |
| 3 | 42 | 21.2 | 100 | 1000 | 335 | 2.11 | Not | Not |
| | | | | | | | measured | measured |
| 4 | 42 | 21.2 | 50 | 300 | 335 | Not | 53.1 | 5.0 |
| | | | | | | measured | | |

| | | | |
|---|---|---|---|
| Fused silica | 2.20 | E = 72.4^{a} | Hv = 7.7 GPa |

^{a}Technical Data Sheet, Shin-Etsu Synthetic Quartz, Shin-Etsu Chemical Co., Ltd.

Fused silica is provided for comparison. The density was measured by XRR. Sample 1 is 83% as dense as the non-porous fused silica, Sample 2 is 89% as dense, and Sample 3 is 96% as dense. Even with a 17% change in relative density for the most porous sample, the modulus of Sample 1 was 49.6 GPa and the hardness was 4.8 GPa. Sample 1 has a ratio of Young's modulus to relative density of (49.6/0.83)=59.8, and a refractive index of 1.47.

### Example 3

A test was developed to provide a comparison of open porosity for different films by dispensing drops of imprint resist on a PECVD silicon oxide surface and observing the drop diameter by optical microscope over time to determine if the resist was penetrating the film. The films listed in Table 6 were deposited on DSP 3″ wafers while the wafers were spaced apart from the chuck by a ¼″ thick polished fused silica plate. Drops that maintained approximately the same diameter for 2 minutes (a slight change can occur due to evaporation) were considered “non-wicking.” Various wicking rates were observed as indicated in Table 6. The wicking rates were seen to vary depending on the deposition conditions as listed in Table 6. The filling rates were obtained from 90 nm thick imprints obtained by depositing droplets spaced 340 μm apart on a rectangular grid in a helium-purged environment. After wicking but before the filling test, the silicon oxide coated wafers were coated with TranSpin™ to (a) seal the open surface pores to prevent resist from wicking in during imprinting and to (b) serve as an adhesion promoter for the resist. Filling times are expected to decrease for highly-polished films as an imprinting surface in comparison to films with rough surfaces. The refractive indices of the films were measured on a J. A. Woollam M-2000 DI ellipsometer.

TABLE 6
Example PECVD process conditions.

| | | | | | | | | | Filling | Film | Refractive |
|---|---|---|---|---|---|---|---|---|---|---|---|
| Film | | N₂O | SiH₄ | Power | Pressure | Temp | Time | | time | Thickness | index at |
| Stack | Layer | (sccm) | (sccm) | (W) | (mTorr) | (° C.) | (min) | Wicking | (sec) | (um) | λ = 600 nm |
| A | Single | 160 | 7.0 | 80 | 800 | 335 | 40 | none | Not | Not | 1.4639 |
| | | | | | | | | | tested | measured | |
| B | Single | 42 | 21.2 | 50 | 450 | 335 | 90 | none | 2.4 | 4.9 | 1.4585 |
| C | Single | 42 | 21.2 | 50 | 300 | 270 | 80 | fast | 1.2 | 4.1 | 1.4717 |
| D | Intermed. | 42 | 21.2 | 50 | 300 | 270 | 80 | none | Not | 4.4 | Not meas. |
| | Cap | 160 | 7.0 | 80 | 800 | 270 | 18 | | tested | 0.4 | |
| E | Single | 42 | 21.2 | 50 | 1000 | 335 | 130 | none | 1.8 | Not | 1.4603 |
| | | | | | | | | | | measured | |
| F | Single | 120 | 21.2 | 100 | 300 | 335 | 80 | none | Not | Not | 1.4487 |
| | | | | | | | | | tested | measured | |
| G | Single | 42 | 21.2 | 50 | 1000 | 335 | 65 | None | 2.1 | 4.3 | 1.4488 |

Film C is porous and is intended to be coated with a cap layer for further processing (e.g., sealing, patterning, and feature etch). This film is an example of a layer that is suitable as a porous first layer (e.g., a porous intermediate layer). The porosity is apparent by the measured density, drop wicking result, and fast filling time compared to the denser single layers listed in Table 6.

Film D includes a cap on Film C. A lower temperature cap process (270° C.) was used which was the same temperature as the first layer. This lower temperature process may reduce unwanted thermal changes in the first (intermediate) layer during the second layer deposition, because the temperature does not exceed above the first layer process.

Films B, E, F, and G were processed at 335° C. and all demonstrate non-wicking attributes. Other process conditions (e.g., gas flow rate, pressure, and power) were varied as noted in Table 6. A denser cap is preferred for patterning of features into a film. Furthermore, films E and G are formed by the same process, but film E is twice as thick (about 8 μm) as Film G (about 4 μm). Film thicknesses were obtained by cross-sectioning and measuring by SEM.

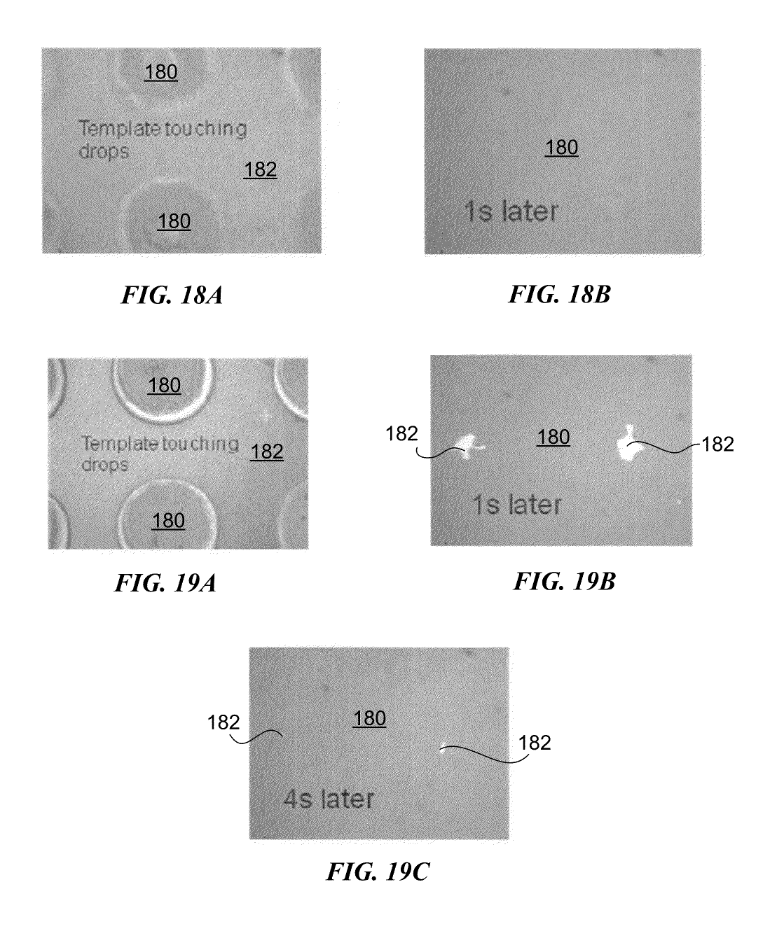

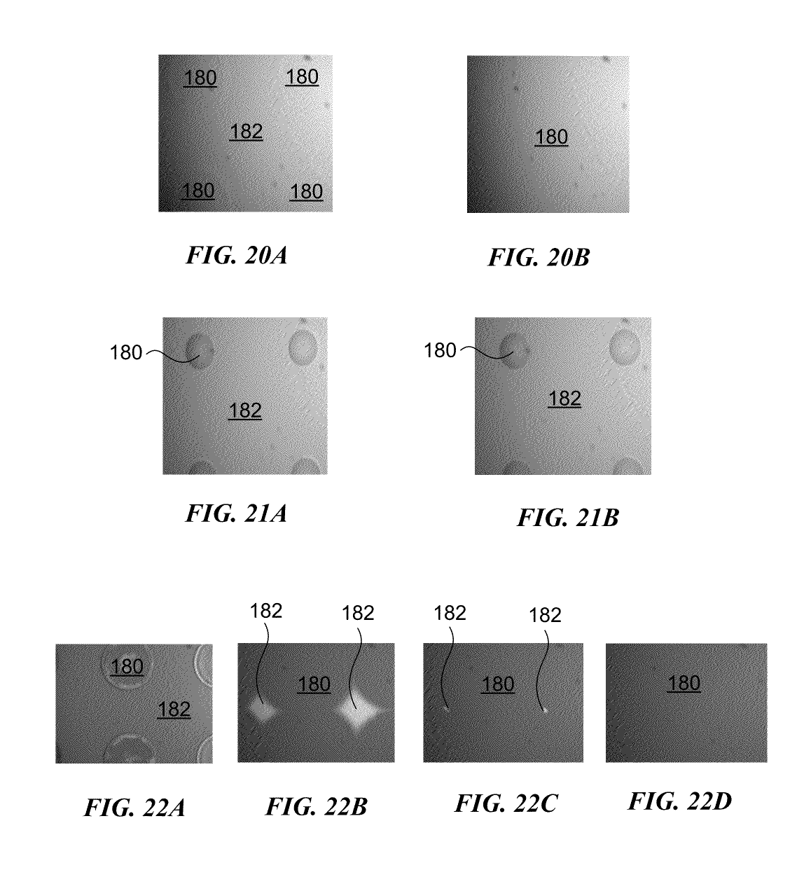

FIGS. 20A and 20B show photographs of wicking of an imprint resist on Film C. The image in FIG. 20A was taken once the wafer stage was settled after the imprint resist was deposited as drops of imprint resist 180 on Film C. The drops of imprint resist 180 penetrate the film quickly. The outlines of the drops are no longer distinguishable in FIG. 20B, taken 5 seconds after the image in FIG. 20A. The drops 180 spread quickly as the gases between the drops diffused through the film

FIGS. 21A and 21B show images of spreading of an imprint resist on Film D. The image in FIG. 21A was taken once the wafer stage was settled after the drops 180 were dispensed onto the film. FIG. 21B, taken 120 seconds later, shows substantially no change in the size of drops 180. Film D is considered to be an example of a non-wicking film.

### Example 4

A fused silica template measuring 65×65×6.4 mm was fabricated with a PECVD porous silicon oxide film to demonstrate enhanced gas diffusion through the template side versus the wafer side. A layer of silicon oxide about 4 μm thick was grown on the surface of a cored-out fused silica template having a mesa measuring 26×32 mm and 15 μm in height. The cored-out region of the template was set on a 2″ diameter×0.25″ thick polished fused silica plate that was placed on the chuck in a PlasmaTherm 790. After deposition of a porous silicon oxide layer, an organic polymer and a silicon-containing polymer were spin coated on top of the porous silicon oxide film to planarize the topography and cap the porous film to prevent imprint resist from penetrating into the oxide. Spin coater CEE® 4000, available from Brewer Science (Rolla, Mo.), was used in the spin coating process. The template was spin coated with 100 nm of TranSpin™ and proximity baked on a hotplate with the coated side facing down at 160° C. for 3 min. The template was then spin coated with 100 nm of a high-silicon containing polymer resist similar to the class of materials described in U.S. Pat. No. 7,122,079, which is incorporated herein by reference, and proximity baked on a hotplate with the coated side facing down at 160° C. for 3 min. Because a mesa was on the template prior to spin coating, an edge bead formed along the sides of the top surface of the mesa, therefore a diced silicon wafer piece measuring approximately 20×20 mm was used as a mask during a dry-etch process to remove the edge bead and to define a new mesa in the silicon oxide layer. The silicon mask was then removed and the template was exposed to low power oxygen plasma to oxidize the surface of the high-silicon containing polymer to impart some SiOₓ character for wetting and release properties. The template was etched and oxidized in an Oracle III etcher available from Trion Technology (Clearwater, Fla.).

The template was imprinted in a helium purged environment on 200 mm DSP silicon wafers coated with 60 nm of TranSpin™. MonoMat® imprint resist, available from Molecular Imprints, Inc., was dispensed in a rectilinear grid pattern having an approximate drop spacing of 340 μm center-to-center to produce imprints about 90 nm thick. As shown in FIG. 22A, interstitial locations 182 between drops of imprint resist 180 were observed by a microscope camera at the time the template contacted the resist. Images in FIGS. 22B, 22C, and 22D were taken 0.3 sec, 0.7 sec, and 1.2 sec, respectively, after the image in FIG. 22A. As seen in FIG. 22D, the interstitial locations 182 disappeared within 1.2 seconds after the resist was contacted by the template, such that the surface of the template was substantially covered with imprint resist.

The photographs shown in FIGS. 19A-19C were taken through a fused silica template that did not contain a porous film, but was imprinted on a similar film stack as above. FIG. 19C shows the interstitial gas pocket remaining after 4 seconds. Thus, the porous silicon oxide layer allowed for the quick uptake of helium, which resulted in the void filling more than 3 times faster than a similar void with a fused silica template which did not have a porous oxide layer.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

1.-22. (canceled)

23. An imprint lithography template comprising:
a first layer;
a second layer, wherein the second layer is a patterned layer of an imprint lithography template; and
two or more intermediate layers positioned between the first layer and the second layer, wherein at least one of the intermediate layers is a porous layer and at least one of the intermediate layers is a stress relief layer configured to reduce a force acting on the porous intermediate layer.

24. An imprint lithography template comprising:
a first layer;
a second layer, wherein the second layer is a patterned layer of an imprint lithography template; and
an intermediate layer positioned between the first layer and the second layer, wherein the intermediate layer is configured to reduce a force acting on the patterned second layer.

25. An imprint lithography template comprising:
a first layer;
a second layer; and
an intermediate layer positioned between the first layer and the second layer of the imprint lithography template, wherein the intermediate layer is configured to allow assessment of a thickness of the second layer based on a difference in physical properties between the intermediate layer and the second layer.

24. The imprint lithography template of claim 23 wherein the relief layer is formed of a material in a compressive state such that a compressive force F_{C} acts on the relief layer.

25. The imprint lithography template of claim 24 wherein the porous layer is subject to intrinsic forces that produce a tensile force F_{T} acting on the porous layer and the compressive force F_{C} acting on the relief layer substantially neutralizes the tensile force F_{T} acting on the porous layer.

26. The imprint lithography template of claim 23 wherein the relief layer is formed of a material in a tensile state such that a tensile force F_{T} acts on the relief layer.

27. The imprint lithography template of claim 26 wherein the porous layer is subject to intrinsic forces that produce a compressive force F_{C} acting on the porous layer and the tensile force F_{T} acting on the relief layer substantially neutralizes the compressive force F_{C} acting on the porous layer.

28. The imprint lithography template of claim 23 wherein the relief layer is formed of a material selected from the group consisting of SiNₓ, SiOxN_{y}, SiCₓ, SiOₓ and diamond-like carbon (DLC).

29. The imprint lithography template of claim 23 wherein the relief layer is permeable to gases selected from the group consisting of helium, nitrogen, oxygen and carbon dioxide.

30. The imprint lithography template of claim 29 wherein the relief layer is permeable to helium.
